(19) United States
(12) Patent Application Publication
(10) Pub. No.: US 2026/0305260 A1
(43) Pub. Date: Oct. 1, 2026

(54) METHOD OF SEPARATING A CHIP FROM A CARRIER AND A SYSTEM FOR PERFORMING THE METHOD

(71) Applicant: CANON KABUSHIKI KAISHA, Tokyo (JP)

(72) Inventor: Nilabh K. Roy, Cedar Park, TX (US)

(21) Appl. No.: 19/092,913

(22) Filed: Mar. 27, 2025

(51) Int. Cl. H01L 21/683; B25B 11/00; H01L 21/67

(52) U.S. Cl. CPC H10P 72/78; B25B 11/005; H10P 72/0428; H10P 72/0446

(57) ABSTRACT

A method of separating a chip from a carrier includes holding the carrier with a chuck such that a first region of the chuck overlaps a central portion of the chip and a second region of the chuck overlaps an outer portion of the chip, applying a first vacuum pressure to the first region and applying a second vacuum pressure to the second region such that a portion of the carrier adhered to the outer portion of the chip separates from the chip while a portion of the carrier adhered to the central portion of the chip remains adhered to the chip, and separating the portion of the carrier adhered to the central portion of the chip from the chip by applying a force to the chip in a direction away from the chuck.

### FIELD OF THE DISCLOSURE

The present disclosure relates to methods of separating chips from a carrier.

### RELATED ART

When bonding chips to a substrate the chips are first separated from a carrier and transferred to a bonding head. When the carrier is relatively rigid (i.e., more rigid than wafer dicing tape) the carrier can be easily handled by standard semiconductor processing equipment and can be subjected to harsher processing conditions (e.g., high temperature, high reactivity, etc.) without damaging the carrier. However, when the carrier is relatively rigid, it can be difficult to separate the chip from the carrier without damaging the chip.

Japanese Patent Publication H02-17651-A discloses a technique where a push-pin presses against a chip as part of a process of separating the chip from a carrier. However, the use of a push-pin is a direct mechanical impingement upon the chip that may damage the chip.

Thus, there is a need in the art for a method and system for separating chips from a carrier without damaging the chip and one that targets individual chips.

### SUMMARY

The present method enables easier peeling, reducing the distortion requirement on the chip side, thus it protects the chip from damage while allowing the chip and the carrier to be peeled away from each other.

A method of separating a chip from a carrier includes holding the carrier with a chuck such that a first region of the chuck overlaps a central portion of the chip and a second region of the chuck overlaps an outer portion of the chip, applying a first vacuum pressure to the first region and applying a second vacuum pressure to the second region such that a portion of the carrier adhered to the outer portion of the chip separates from the chip while a portion of the carrier adhered to the central portion of the chip remains adhered to the chip, and separating the portion of the carrier adhered to the central portion of the chip from the chip by applying a force to the chip in a direction away from the chuck.

A system for separating a chip from a carrier comprises a chuck having a first region and a second region, a vacuum supply, a die pickup member, one or more processors, and one or more memories storing instructions, when executed by the one or more processors, causing the system to: actuate the vacuum supply to hold the carrier with the chuck such that the first region of the chuck overlaps a central portion of the die and the second region of the chuck overlaps an outer portion of the die, actuate the vacuum supply to apply a first vacuum pressure to the first region and to apply a second vacuum pressure to the second region such that a portion of the carrier adhered to the outer portion of the die separates from the die while a portion of the carrier adhered to the central portion of the die remains adhered to the die, and actuate the die pickup member to separate the portion of the carrier adhered to the central portion of the die from the die by applying a force to the die in a direction away from the chuck.

A method of manufacturing an article comprises holding a carrier with a chuck such that a first region of the chuck overlaps a central portion of a die and a second region of the chuck overlaps an outer portion of the die, applying a first vacuum pressure to the first region and applying a second vacuum pressure to the second region such that a portion of the carrier adhered to the outer portion of the die separates from the die while a portion of the carrier adhered to the central portion of the die remains adhered to the die, separating the portion of the carrier adhered to the central portion of the die from the die by applying a force to the die in a direction away from the chuck, actuating a bonding head to cause the separated die to bond to a bonding surface of a substrate, and singulating the substrate to produce the article.

### BRIEF DESCRIPTION OF THE DRAWINGS

Implementations are illustrated by way of example and are not limited in the accompanying figures.

FIG. 1 shows a schematic side view of a chip bonding system, in accordance with an example embodiment.

FIG. 2 shows a schematic enlarged view of a portion of FIG. 1, in accordance with an example embodiment.

FIG. 3 shows a flowchart of a method for separating a chip from a carrier, in accordance with an example embodiment.

FIG. 4A is a schematic bottom view of a carrier chuck, in accordance with an example embodiment.

FIG. 4B is a schematic cross-section view taken along line 4B-4B of FIG. 4A.

FIG. 5 is a schematic cross-section view taken along line 4B-4B of FIG. 4A when a carrier with chips is being held by the carrier chuck, in accordance with an example embodiment.

FIG. 6 is a schematic bottom view of the carrier chuck showing the position of the chips projected onto the carrier chuck, in accordance with an example embodiment.

FIG. 7A is a schematic cross-section view taken along line 4B-4B of FIG. 4A when the carrier with chips is being held by the carrier chuck and during a step in the method of separating the chips from the carrier, in accordance with an example embodiment.

FIG. 7B is an enlarged portion 7B of FIG. 7A.

FIG. 8 is a schematic cross-section view taken along line 4B-4B of FIG. 4A when the carrier is being held by the carrier chuck and after the chips have been separated from the carrier, in accordance with an example embodiment.

FIG. 9 is a schematic cross-section of the carrier chuck in another example embodiment when the carrier has chips that are smaller in the example embodiment of FIG. 7A, and during a step in the method of separating the chips from the carrier.

FIG. 10A is a schematic cross-section of the carrier chuck in another example embodiment when the carrier has chips that are smaller in the example embodiment of FIG. 9, and during a step in the method of separating the chips from the carrier.

FIG. 10B is an enlarged view of portion 10B of FIG. 10A.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the invention.

### DETAILED DESCRIPTION

The following description in combination with the figures is provided to assist in understanding the teachings disclosed herein. The following discussion will focus on specific implementations and implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

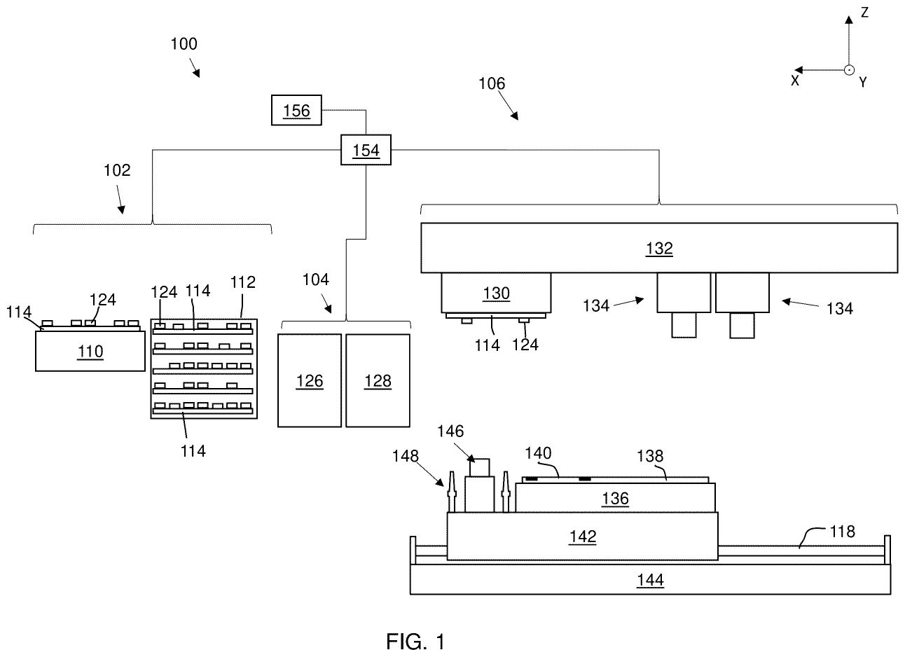

FIG. 1 shows a schematic side view of a chip bonding system 100 in accordance with an example embodiment. As shown in FIG. 1, the bonding system 100 includes a chip source section 102, a chip transfer and activation section 104, and a chip bonding section 106. The chip source section 102 is the portion of the overall chip bonding system 100 that contains the source chips that will be used in the bonding process. The chip transfer and activation section 104 is the portion of the overall chip bonding system 100 that transfers the chips from the chip source section 102 to the chip bonding section 106. In another configuration, the chip source section can be a separate apparatus. Similarly, the chip activation section can be a separate apparatus. The chip transfer and activation section 104 also activates the source chips so the source chips are ready for bonding. In an alternative embodiment, the activation section 104 activates the plurality of chips 124 prior to the chips being placed in the chip source section 102. The chip bonding section 106 receives chips that have been activated and then performs the bonding.

The chip source section 102 includes one or more sources for chips. For example, as shown in FIG. 1, the chip source section may include a carrier 114 held by a source chuck 110 with chips 124 thereon and/or may include a front opening unified/universal pod 112 (known in the art as a “FOUP”). The FOUP 112 may include a plurality of the carriers 114 and chips 124. The carrier 114 is for example a wafer substrate. In the chip separating method described herein, the carrier 114 is rigid. Rigidity is dependent upon the Young's modulus of the carrier material and the thickness of the carrier. The Young's modulus of the carrier may be between 1 to 200 GPa, preferably between 50-200 GPa. The thickness of the carrier may be 2 mm or greater. A flexible carrier that is not considered to be a rigid substrate would be very thin (less than 0.2 mm) and/or have a Young's modulus of less than 4 GPa. When the carrier is made of a material with a low Young's modulus (for example less than 30 GPa), then the carrier would need be relatively thicker to be rigid, for example a thickness greater than 2 mm. The rigid carrier needs to have enough flexural rigidity such that the rigid carrier maintains it shape even while being supported by a handling robot at 3-5 or less contact points. The rigid carrier also needs to have enough flexural rigidity such that the rigid carrier maintains it shape even when being unevenly loaded. This allows standard semiconductor handling robots to be used for moving the carrier through the various process steps required by the bonding process. Example materials for the carrier 114 include any one or combination of glass, silicon, quartz, and gallium arsenide. Each of these examples are rigid. As used herein, a chip means an integrated circuit, also referred to as a microchip, a computer chip, a MEMS device, an optical device, an electrical-optical device, a microfluidics device, etc. A chip can be any device that has a set of interconnect contacts that are to be bonding to corresponding interconnect contacts on the product substrate. A chip may be defined as a small block of semiconducting material on which a given functional circuit is fabricated. In the context of a wafer/substrate that has been divided into individual chips, the chip is known as a die. The chip will typically carry a set of integrated electronic components and circuits formed on it by patterning, coating, etching, doping, plating, singulating, etc. The chip will typically have electrical functions such as: memory, logic, field programmable gate arrays (FPGA), accelerator circuits, application-specific integrated circuits (ASICs), security co-processors, graphics processing units (GPUs), neural processing unit (NPU) machine learning circuits, specialized processors, controllers, devices, electrical circuits, arrays of passive components, etc. The chip may also be a micro-electromechanical systems (MEMS) device, an optical device, an electrical-optical device, etc. The chip may generally have a Young's modulus of 130 to 188 GPa with a thickness of 50-750 μm and is more rigid (the rigidity is, in general, a function of young's modulus and the thickness) than the carrier.

The chip transfer and activation section 104 includes a transfer robot 126 that is able to lift and carry the carrier 114 to a carrier chuck 130 in the bonding section 106. As understood in the art, the transfer robot 126 generally includes a hand and a robot arm that provides the degrees of motion to lift, carry, and place a carrier from one location to another, such as from one carrier chuck to another or from a carrier storage location to a carrier chuck. The transfer robot 126 may be any suitable device known in the art, for example robots such as the wafer handling robot RR756L15 provided by Rorze Corporation of Fukuyama-shi, Hiroshima-ken, Japan. The chip transfer and activation device 104 further includes an activation device 128. The activation device 128 is a device that prepares the chips being transferred for hybrid bonding. Hybrid bonding is a chip bonding technique in which electrically insulating (silicon dioxide) chip surfaces with recessed metallic (e.g. copper) pads are brought into contact with each other. The metallic pads are aligned with each other, while the electrically insulating surfaces are bonded to each other via direct contact. Heat is then applied to the bonded structure which causes the metallic pads to expand more relative to the electrically insulating material and contact each other, thus forming electrical connections between the chips. In an example embodiment, the activation device 128 may include a fluid source that applies for example deionized water and possibly a plasma source that activates the surface of the chips prior to them being carried by the transfer robot 126. Due to the materials of the chips (i.e., dielectric) and their smoothness, when the activated chip is brought into contact with another chip a fusion bond will occur between the dielectric surfaces of the two chips.

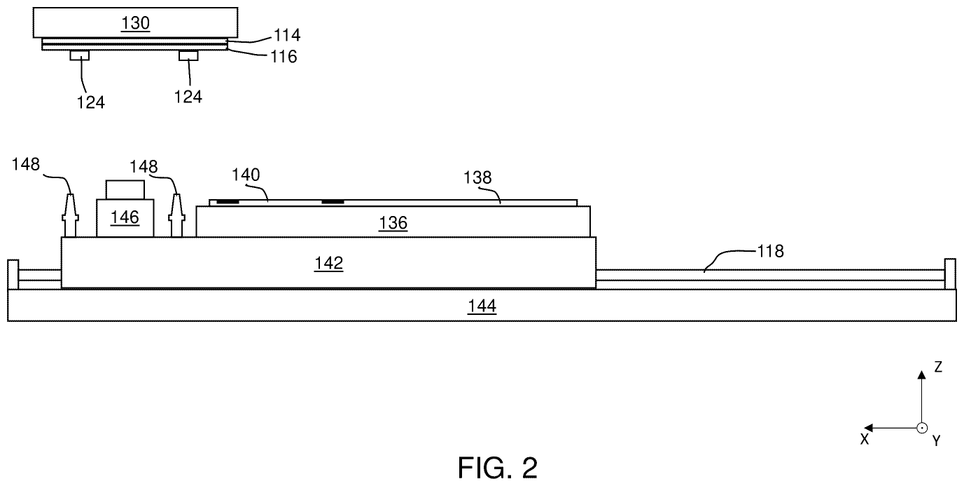

FIG. 2 shows a portion of the bonding section 106 that are relevant to separating the chips from the carrier 114. Referring to both FIGS. 1 and 2, the bonding section 106 includes the carrier chuck 130 for receiving the carrier 114 that has been carried by the transfer robot 126 and has chips that have been activated by the activation device 128. The carrier chuck 130 may also be referred herein as an intermediate chuck because it holds the carrier before the chips are separated and moved to another location for bonding. As shown in FIG. 2, the chips 124 are adhered to the carrier 114 via an adhesive 116. As will be explained in more detail below, one side of the carrier 114 comes into direct contact with the carrier chuck 130, while the adhesive 116 is on the side of the carrier 114 opposite to the side that contacts the carrier chuck 130. The side of the adhesive 116 not contacting the carrier 114 is in contact with the chips 124. The adhesive may be for example WaferBOND® HT-10.11 from Brewer Science, Inc. of Rolla, MO. The adhesive may be any of one many commercially available temporary adhesives that meet the cleanliness standards of the semiconductor industry. The adhesive layer may include a release layer or release compound. The adhesive layer can be designed to work in combination with a detack process. The detack process reduces the adhesive strength of the adhesive layer. Examples of detack processes are: radiation treatment (for example UV or IR); liquid treatment; and gas treatments. The adhesive may have a peel strength of for example 0.05 N/25 mm to 0.1 N/25 mm after the detack process. Prior to the detack process the adhesive can have a peel strength of 3 N/25 mm to 7 N/25 mm.

Returning to FIG. 1, the bonding section 106 may include a bridge 132 to which the carrier chuck 130 is attached. The bonding section 106 also includes a plurality of bonding heads 134 attached to the bridge 132. The bonding heads 134 may include a bonding head base, a bonding head stage, bonding head sensors, and a chip bonding chuck. The bonding head sensors can include interferometric, spectral interference, linear encoders, rotary encoders, capacitive sensors, potentiometric sensors, inductive sensors etc. that are used to provide information of the relative position of the chip bonding chuck. A processor 154 may use information from the bonding head sensors to control the position of chip bonding chuck with the bonding head stage. The chip bonding chuck holds the back surface of the chips 124. While two bonding heads are shown in FIG. 1, additional bonding heads may be present. The bonding head stage may include one or more actuators that move the chip bonding chuck in at least the Z direction towards a product substrate chuck 136. The chip bonding chuck may hold the chip 124 to the chucking surface of the bonding head using: vacuum forces; electrostatic forces; electromagnetic forces; mechanical gripping forces; or any other method of releasably holding the chip to the chucking surface of the bonding head 134. The bonding section 106 further includes a product substrate chuck 136 holding a product substrate 138. The product substrate 138 has a bonding surface 140. The bonding surface 140 in the illustrated example embodiment is the upper surface of the product substrate 138. In another example embodiment, the bonding surface may be a surface of a chip already on the product substrate 138. That is, the bonding described herein may be used to bond source chips onto the surface of a product substrate and/or may be used to bond source chips to the surface of a product chip on the product substrate. The bonding heads are not illustrated in FIG. 2.

As shown in FIGS. 1 and 2, the bonding system 106 further includes a carriage 142 that supports the product substrate chuck 136 and the one or more transfer heads 148 and one or more alignment devices (not shown). The carriage 142 may rest on bearings 118 and may be part of a product substrate chuck positioning system. The product substrate chuck positioning system may include one or more motion stages for providing up to 6 degree of freedom motion of the substrate chuck relative to the parallel set of bonding heads.

As noted above, the bonding section 106 may further include one or more transfer heads 148 and a plurality of alignment devices 146 all of which are also carried by the carriage 142. As shown in FIG. 1, the bearings 118 of the carriage 142 may support the alignment devices 146 and the transfer heads 148. The transfer head is also referred to herein as chip pickup member because the transfer head picks up the chip from the carrier as part of the method of separating the chip from the carrier described below. Each of the plurality of transfer heads 148, may include any one of a variety of methods of holding the chips including but not limited to: a Bernoulli chuck; a suction nozzle; an electrostatic chuck; an edge gripping chuck; a latching mechanism; or any method of releasably holding a chip. Each of the plurality of transfer heads 148, may include an actuator for moving in at least the Z direction towards and away from the bridge 132. The plurality of alignment devices 146 are used to examine the alignment of chips on the plurality of bonding heads 134 after the chips have been transferred to the plurality of bonding heads 134. Each alignment device may be a microscope, a camera, an interferometer, or any sort of measuring device that is capable of measuring the position of each chip on a sub-mm, micron, or nanometer scale. The information provided by the plurality of alignment devices 146 will allow the operator to know whether each chip is at a target position within an acceptable amount of error. The plurality of alignment devices 146 may be any suitable device known in the art, for example a 20× microscope with 5 megapixel camera such as a CI-5MGMCL from Canon Inc., of Tokyo Japan. The plurality of transfer heads 148 are used to transfer the chips from the substrate 114 that is held by the carrier chuck 130 to the plurality of bonding heads 134.

The number of transfer heads 148 of the plurality of transfer heads may be 1 to 300, 5 to 100, or 8 to 16, for example. The arrangement of the transfer heads 148 may be in the form of columns and rows such as one by two, two by one, two by two, one by three, three by one, two by three, three by two, three by three, four by one, one by four, four by two, two by four, three by four, four by three, four by four, etc. In the illustrated example embodiment, the transfer heads 148 are two by two, for a total of four transfer heads. The number and arrangement of transfer heads may be the same as the number and arrangement of chips adhered to the carrier 114. Or the number and arrangement of transfer heads can be larger than those of the chips adhered to the carrier 114.

The bonding section 106 may further include a microscope (not shown) on the carriage 142 and a microscope (not shown) on the bridge 132. The microscope on the carriage 142 is moveable along with the plurality of transfer heads 148, the product substrate chuck 136, and the plurality of alignment devices 146. The microscope on the carriage is aimed upwardly in a direction toward the intermediate carrier chuck 130. The microscope on the carriage functions to measure positions of the plurality of chips on the substrate 114. The microscope on the bridge faces downward in a direction toward the product substrate chuck 136. The microscope on the bridge functions to measure positions of the chips on the product substrate 138. Each of the microscopes may be suitable device known in the art, for example a 20× microscope with a 5 megapixel camera such as a CI-5MGMCL from Canon Inc., of Tokyo Japan.

The bonding system 100 may be regulated, controlled, and/or directed by one or more processors 154 (controller) in communication with one or more components and/or subsystems such as the chip source section 102, the chip transfer and activation section 104, the bonding section 106, the source chuck 110, the FOUP 112, the transfer robot 126, the activation device 128, the carrier chuck 130, the plurality of bonding heads 134, the sensors, the product substrate chuck 136, the product substrate positioning system including the carriage 142, the plurality of alignment devices 146, the plurality of transfer heads 148, a plurality of vacuum sources that provide controlled vacuum pressures to the carrier chuck 130 described below, and any microscopes. The processor 154 may operate based on instructions in a computer readable program stored in a non-transitory computer memory 156. The processor 154 may be or include one or more of a CPU, MPU, GPU, ASIC, FPGA, DSP, and a general-purpose computer. The processor 154 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the steps described herein may be executed by the processor 154.

As part of the overall bonding and manufacturing of an article, first, desired chip information may be received, including what quality of chips are needed and where the chips are to be placed on the bonding surface. The quality of the chips can be defined as maximum clock rate, percentages of functioning transistors at one or more specified clock rates, local cache size, thermal conductivity, and other properties which affect the performance of the chips which can vary depending on the fabrication performance of the chip. After receiving the chip information, if not already activated, the transfer robot 126 may carry a carrier 114 through the activation device 128 to activate the chips in the manner described above, after which the carrier 114 is received by the chip bonding section 106. After passing through the activation device 128, with the chips activated, the transfer robot 126 will then carry the carrier 114 to the carrier chuck 130 of the chip bonding section 106. In an alternative embodiment, the chips on the carrier 114 are already activated and are transferred directly to the bonding section 106 from the chip source section 102.

The carrier 114, having the activated chips 124 secured thereon via the adhesive 116, may then be chucked to the carrier chuck 130. Next, once the carrier 114 having the activated chips 124 has been mounted to the carrier chuck 130, a microscope may be used to measure the position of the plurality of chips 124. This step may be performed by moving the carriage 142 until the microscope is beneath the plurality of chips 124. If the feedback from the first microscope shows that the certain chips of the plurality of chips 124 are outside of an acceptable amount of error, then a replacement carrier 114 would need to prepared. If the feedback from the microscope shows that the plurality of chips 124 are located at the proper positions within an acceptable amount of error, the method may proceed.

Some or all of the chips adhered to the carrier 114 may be then transferred to the plurality of bonding heads 134. Transferring the chips 124 from the carrier includes separating the chips adhered to the carrier 114 by performing the separating method 300 described below. The plurality of transfer heads 148 may include the same number of heads with the same pitches as the plurality of bonding heads 134. The plurality of transfer heads 148 are configured to mirror the plurality of bonding heads 134 so that the plurality of transfer heads 148 can transfer up to the same number of chips that the plurality of bonding heads are capable of bonding in a single bonding step.

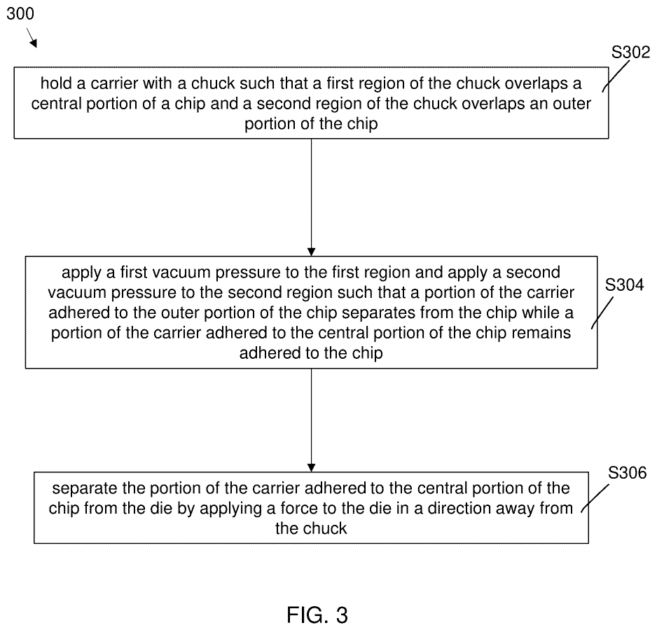

FIG. 3 shows a flowchart of a method 300 for separating the chip 124 from the carrier 114 using the bonding system 100. The method 300 begins with step S302 where the carrier chuck 130 holds the carrier 114 such that a first region of the chuck overlaps a central portion of the chip and a second region of the chuck overlaps an outer portion of the chip. This step is performed as part of the chucking the carrier 114 to the carrier chuck 130.

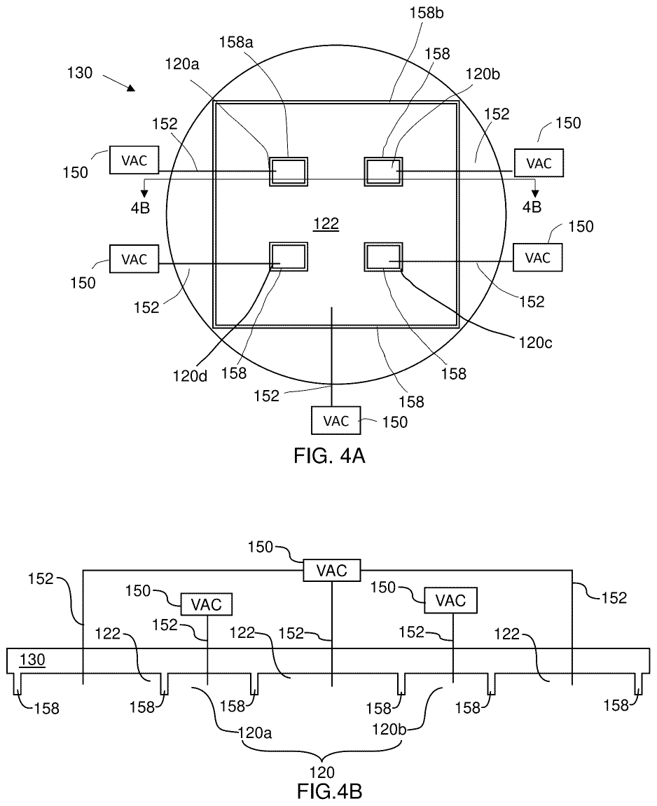

FIG. 4A shows a schematic bottom view of the carrier chuck 130 used in the method 300 prior to chucking the carrier 114. FIG. 4B shows a schematic cross section taken along line 4B-4B of the carrier chuck 130 used in the method 300 prior to chucking the carrier 114. The carrier chuck 130 may include multiple regions in communication with multiple vacuum sources 150 that allow the carrier chuck to be used to assist in separating the chips from the carrier according to the method 300. As seen in FIGS. 4A and 4B the carrier chuck 130 includes a plurality of first regions 120 and a plurality of second regions 122. In the example shown in FIGS. 4A and 4B the first plurality of regions 120 have four first distinct regions 120a, 120b, 120c, 120d spaced apart from each other. However, the first set of first regions may include from 4 to 5000 regions, more preferably 25 to 3000 regions. The number of first regions 120 may be the same as or greater than the number of chips 124 adhered to the carrier 114. The second region 122 may be adjacent to the plurality of first region 120. In particular, the plurality of first regions 120 may be located within and surrounded by the second region 120, as best seen in FIG. 4A. The ratio of the total surface area encompassed by all of the first regions 120 to the area encompassed by the second region 122 may be 5% to 95%. The ratio encompassed by a single one of the first regions 120 to the area encompassed by the second region 122 may be 0.001% to 24%.

Each of the first regions 120 and the second region 122 may be in communication with a vacuum source 150 via a communication path 152. While shown schematically in FIGS. 4A and 4B, the communication paths 152 may include passageways formed in the body of the carrier chuck 130, connection ports, and tubing, and the like such that a vacuum suction can be applied to each of the regions 120, 122 by actuating the vacuum source 150. That is, the communication paths 152 are air/vacuum communications paths between the regions 120, 122 and the vacuum sources 150.

While the second region 122 is illustrated as a single region encompassing all the plurality of first regions 120, in another example embodiment, there may be a plurality of second regions. For example, for each first region, there may be a corresponding second region that surrounds the first region. For example, in the view shown in FIG. 4A, instead of the second region being much larger and encompassing all of the smaller first regions, the number of second regions may be equal to the number of first regions, where each second region surrounds only one of the first regions. The ratio of the area of a first region to an area encompassed by the second region may be 5%-95%. The area encompassed by the second region is the sum of the first region and the second region. By having a second region for each first region, the vacuum applied to each second region can be individually controlled. That is, each second region may have a unique vacuum source to control each sound region on an individualized basis.

The plurality of first regions 120 may be separated from the second region 122 by a plurality of lands 158. That is, each region of the plurality of first regions 120 and the second region 122 may be defined by the lands 158. As best seen in FIGS. 4A and 4B, in the illustrated example, each land 158 may include two sets of parallel segments extending from the bottom of the body of the carrier shuck 130, thereby defining the regions as rectangles. This is the case because chips generally have a rectangular shape. The lands can be tailored to have a shape that matches the shape of the chip. Because each of the first regions and the second region are separated by the lands 158, the vacuum source in communication with each region can individually supply a vacuum pressure to one region independently of the other regions. That is, as shown in FIGS. 4A and 4B, each first region 120 is isolated from the other first regions 120 while also being isolated from the second region 122 via the lands. Accordingly, the vacuum applied to one of the first regions does not impact the vacuum the vacuum applied to another one of the first regions nor the second region 122. For example, a first vacuum pressure could be applied to one of the first regions (120a), a second vacuum pressure different from the first vacuum pressure could be applied to the second region 122, and a third vacuum pressure different both the first and the second vacuum pressures could be applied to another one of the first regions (120b).

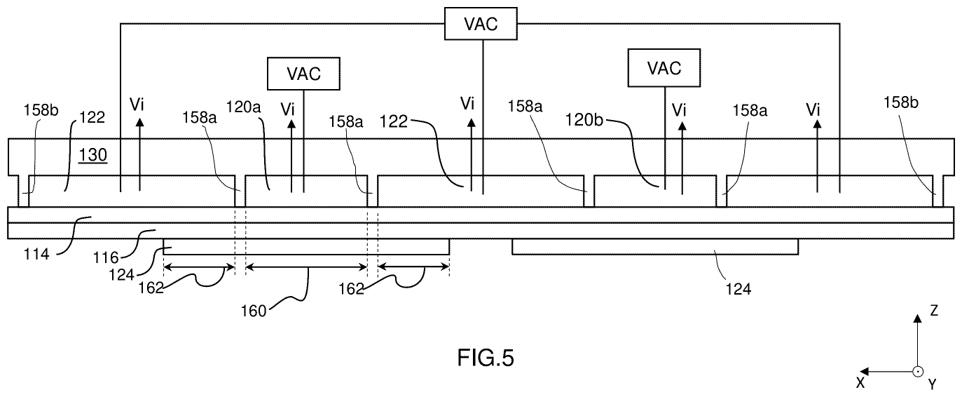

FIG. 5 shows the same schematic cross section view of FIG. 4B at the moment after step S302 is completed, where the carrier chuck 130 is holding the carrier 114 such that the first region 120 (120a, 120b) of the carrier chuck 130 overlaps a central portion 160 of the chip 124 and the second region 122 of the carrier chuck 130 overlaps an outer portion 162 of the chip 124. As seen in FIG. 5, when the carrier chuck 130 is holding the carrier 114, the first region 120 (120a, 120b) overlaps the central portion 160 of the chip 124 while the second region 122 overlaps the outer portion 162 of the chip 124. The outer portion 162 of the chip 124 is adjacent to the central (or inner) portion 160 of the chip 124. The outer portion 162 also surrounds the inner central portion 160. The central portion 160 of the chip 124 may also be defined as the area of the chip that falls within the lands 158a that define the first region 120, while the outer portion 152 of the chip may be defined by the area of the chip that falls outside the lands 158a that define the first region 120 but also falls within the lands 158b that define the second region 122. As seen in FIG. 5, the first regions 120 are smaller than a chip and have a width that is smaller than a width of the chip. The second region 122 may be larger or smaller than the chip, but when the carrier chuck 130 is holding the carrier 114, the second region 122 is positioned to extend outside of the first region 120 and extend beyond the width of the chip. The central portion may be 25-95% of a surface area of the chip, with the outer portion being 5% to 75% of the surface area of the chip. In another aspect, the central portion may be 50% to 75% of the surface area of the chip, with the outer portion being 25% to 50% of the surface area of the chip. When the carrier chuck 130 is holding the carrier 114, the lands 158a of the carrier chuck 130 may overlap less than 1% of the surface area of a chip 124.

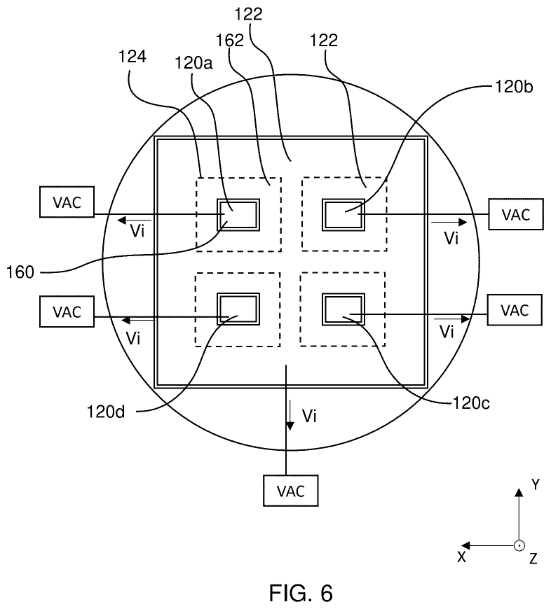

FIG. 6 shows the same bottom view of FIG. 4A at the same moment in FIG. 5 when the step S302 is completed, with the structure of the carrier 114 and adhesive 116 omitted for clarity. The chips 124 are shown as projections in dashed lines to show how the chips overlap with the regions 120, 122 when the carrier chuck 130 is holding the carrier 114 with the chips 124 adhered thereon via the adhesive 116. As shown in FIG. 6, when carrier chuck 130 is holding the carrier 114 with the chips 124, the central portion 160 of the chips overlap the first region 120 while the outer portion 162 of the chips 124 overlap the second region 122.

In order to hold the carrier 114, an initial vacuum pressure Vi may applied to the all the regions of the carrier chuck 130. The initial vacuum pressure Vi may be 5 kPa to 90 kPa. The vacuum pressure Vi is relatively low enough to hold the carrier 114 without deforming the carrier 114 or the adhesive 116. That is, the initial vacuum pressure Vi may be applied to chuck the carrier 114 to the carrier chuck 124, which occurs as part of step S302 and prior to performing step S304.

After step S302, the method 300 my proceed to step S304 where a first vacuum pressure V1 is applied to the first region 120 and a second vacuum pressure V2 to the second region 122 such that a portion of the carrier adhered to the outer portion 162 of the chip 124 separates from the chip 124 while a portion of the carrier adhered to the central portion 160 of the chip 124 remains adhered to the chip 124. The separation of a portion of the carrier 114 (and adhesive 116) from the outer portion 162 of the chip 124 in the second region 122, but not from the inner portion 160 of the chip 124 in the first region 120, may be achieved using relatively low first vacuum pressure V1, a relatively high second vacuum pressure V2, along with an opposing force imparted on the chip 124 in a direction way from the carrier chuck 130. In particular, the second pressure V2 is higher than the first vacuum pressure V1, with the second vacuum pressure V2 imparting a first force F1 in a direction away from the chip 124 toward the carrier 130. The first force F1 is a function of vacuum pressure in the second region 122 and an area of the vacuum zone. At the same time an opposing force F2 may be applied to the chip 124 in a direction away from the carrier 114 and away from the carrier chuck 130. By applying a higher vacuum pressure V2 to the second region 122 imparting the first force F1, and applying a lower vacuum pressure V1 to the first region 120, while applying a second force F2 to the chip 124 in a direction away from the carrier chuck 130, the carrier 114 (and adhesive 116) in the second region 122 lifts up toward the body of the carrier chuck 130 while the carrier 114 stays adhered to the chip 124 in the first region 120. In other words, the second vacuum pressure V2, and the second force F2 are selected such that there is strong enough first force F1 and strong enough second force F2 to overcome the adhesive/peeling force holding the chip 124 to the carrier. At the same time, the first vacuum pressure V1 imparts a force that in the first region 120 that is insufficient to overcome the adhesive force of the adhesive 116. In one example embodiment the adhesive strength/peeling strength may be weakened by performing a weakening step (also known as a deteck process). The weakening step may include exposing the adhesive to UV radiation. The specific adhesives are designed to work with specific weakening steps specified by the adhesive manufacturer. The weakening step may also include UV radiation, IR radiation, microwave radiation, ultrasonic radiation, heat, and/or chemical exposure which reduce the peel strength while not damaging the chips. After weakening the adhesive/peeling strength may be at least 97% less than the adhesive/peeling strength prior to the weakening step.

The transfer heads 148 may be used as the device that applies the second force F2 in the opposite direction to the first force F1 imparted by the vacuum pressure V2. For each chip 124, while the first vacuum pressure V1 and the second vacuum pressure V2 is being applied, a corresponding transfer head 148 may be engaged with the exposed surface of the chip 124. The transfer head 148 may engage with the chip 124 by being positioned very closely underneath the chip 124 while applying a vacuum pressure Vp in the direction opposite the vacuum pressures V2. Once the transfer head 148 is engaged with the chip 124, the transfer head may move downward in the direction away from carrier chuck 130, thereby imparting the second force F2 on the chip 124 in the direction away from the carrier chuck 130. The transfer heads 148 may have a holding region that is larger than the first region 122 of the carrier chuck 130. The engaging of the transfer head with the chip may include engaging the holding region of the transfer head along a perimeter of the chip. In alternative embodiment, the transfer head 148 does not use vacuum to engage the chip 124 and instead uses electrostatic forces, mechanical forces, or Bernoulli forces (also uses vacuum). The structure of the carrier chuck 130 allows for the area of the chip 124 that is attached to the adhesive 116 to be reduced and thus reduce the amount of force that needs to be applied by transfer head 148 to remove the chip 24 from the adhesion layer 116. The structure of the carrier chuck 130 also allows for a central portion of the chip to be supported in a flat manner during the peeling process which prevents bending of the chip 124 during the peeling process and prevents large (greater than 10 mm²) thin (less than 100 μm) chips from being damaged.

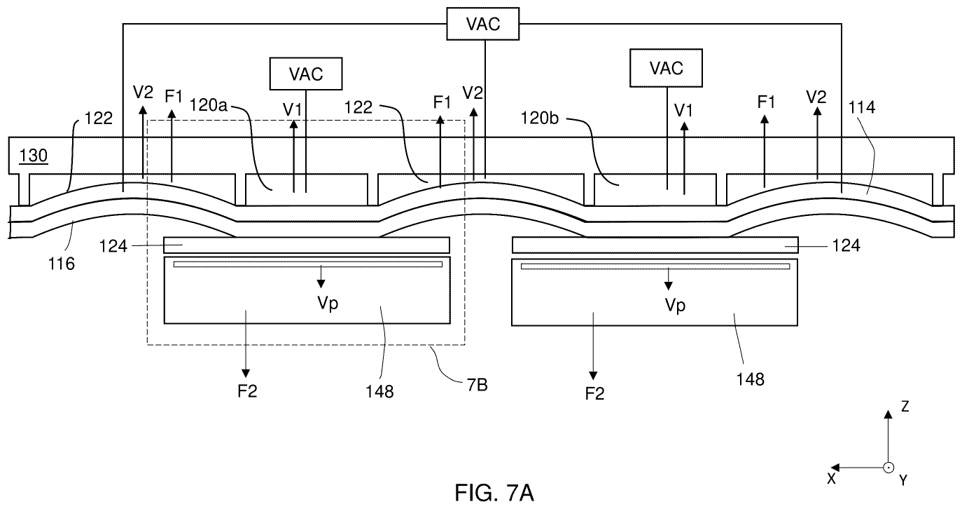

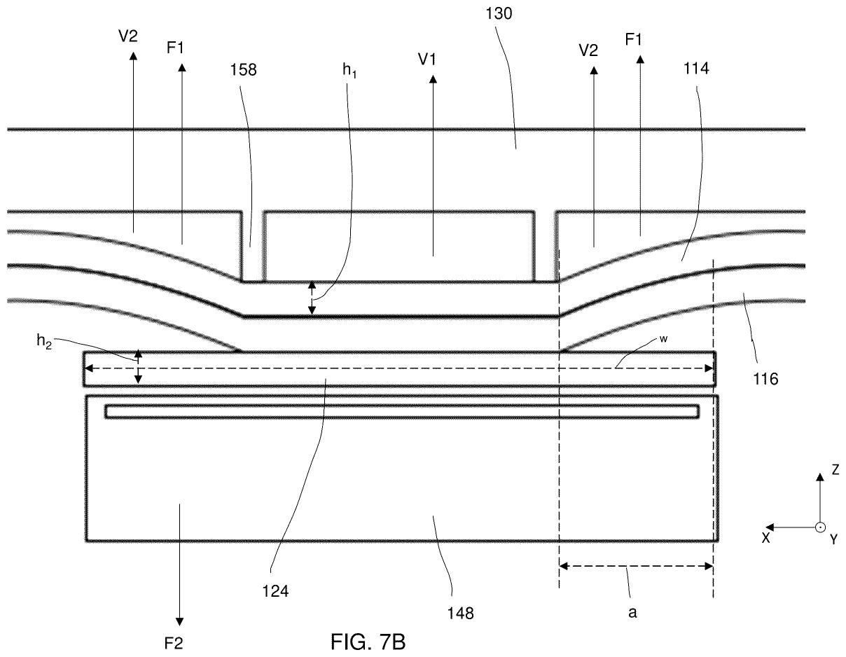

FIG. 7A shows the same cross section view of FIG. 4B at a moment after completing step S302, where the carrier 114 (and adhesive 116) has separated from the outer portion 162 of the chip 124 in the second region 122 and where the carrier 114 (and adhesive 116) has not separated from the center portion 160 of the chip 124 in the first region 120. FIG. 7A shows an enlarged portion 7B of FIG. 7A. As shown in FIGS. 7A and 7B, the transfer head 148 positioned very closely underneath the exposed surface of the chip 124 while applying a vacuum pressure Vp in the direction opposite the vacuum pressures V1, V2. As result of the adhered side of the chip 124 being subjected to the lower vacuum pressure V1 at the center portion 160 and subjected to the higher vacuum V2 at the outer potion 162, while at the same time imparting the second force F2 using the transfer head 148, a portion of the carrier 114 in the second region 122 is separated from the chip 124 while the carrier remains adhered to the chip 124 in the first region 120.

The amount of the first vacuum pressure V1 is selected such that a minimum amount of force to securely hold the carrier 114 to the chuck 130. The first vacuum pressure V1 may be 1 kPa to 60 kPa. The second vacuum pressure V2 may be 10 kPa to 90 kPa. The first vacuum pressure is always less than the second vacuum pressure by at least 5 kPa. The amount of second vacuum pressure V2 that provides the amount of first force F1, and the amount of the second force F2, that together are sufficient to achieve a separation amount may be determined through experimentation or through modeling. The following formula (1) may be used to determine chuck design parameters which results in an “a” for the ranges of forces F1 and F2 that the particular fabrication system can provide, that will result in the desired separation:

$$G = ( F 1 + F 2 ) \frac{3 {a}^{2}}{{w}^{2}} ( \frac{{( 1 + \frac{0.64 {h}_{1}}{a} )}^{2}}{E 1 {h}_{1}^{3}} + \frac{{( 1 + \frac{0.64 {h}_{2}}{a} )}^{2}}{E 2 {h}_{2}^{3}} ) \qquad ( 1 )$$

In formula (1):
G is the energy release rate
F1 is the first force on the carrier 144 in a direction away from the chip 124 toward carrier chuck 130, caused by the vacuum V2 described above
F2 is the second force on the chip 124 in a direction away from carrier chuck 130, caused by the transfer head/pickup member described above, caused by the transfer head described above
a is the separation width
w is the chip width
h₁ is the carrier thickness
h₂ is the chip thickness
E1 is the Young's modulus of the carrier
E2 is the Young's modulus of the chip.
   Equation (1) is a one dimensional model based on beam bending theory that is used to guide the building of a 3D model (for example a finite element model) that describes the peeling of the chip from the adhesive, which is then used to design the chuck.

When G is greater than the peeling strength/interfacial toughness of the adhesive, the separation of the chip from the adhesive will occur. The peeling strength of the adhesive can be lowered, for example, by a weakening step of exposing the adhesive radiation (UV radiation, IR radiation, microwave radiation, ultrasonic radiation) heat, and/or chemical exposure. That is, an adhesive weakening step may be performed prior to performing step S304. The peeling strength of the adhesive at the time of separation is a predetermined value based on the particular adhesive material after any weakening has been performed. The chip width w, the carrier thickness h₁, and the chip thickness h₂ may also be predetermined values for a particular fabrication. The Young's modulus E1 of the carrier is a predetermined property of the material that the carrier is made of and the Young's modulus E2 of the chip is a predetermined property of the material that the chip is made of. The separation width “a” is a desired separation distance in the width direction of the chip (X dimension). However, the separation will also occur along the other surface area dimension perpendicular to the width dimension (Y dimension). That is, the separation width “a” represents an area of separation spanning the X/Y dimensions and is not just separation in the X dimension. As noted above, the peeling strength/interfacial toughness (with or without weakening is also known) as a property of the particular adhesive. Thus, using Formula (1) one can determine what forces F1, F2, and “a” would result in a satisfactory G to achieve separation, i.e., the values of F1, F2, and “a” that would result in a G value that is greater than the peeling strength/interfacial toughness of the adhesive. The F1 value may then be used to determine the corresponding V2 value that would impart the first force F1.

In certain embodiments various aspects of the particular fabrication may be controllable so that a separation width can be achieved with different forces F1 and F2. For example, the carrier thickness h₂ may be customized, the material of the carrier may be customized (i.e., changing the Young's modulus E1), and even the position of the lands of the chuck may be customized. Thus, for a particular fabrication, it is possible to use Formula (1) to determine a preferred material for the carrier, a preferred thickness of the carrier, a preferred lands geometry of the carrier chuck, etc., that will achieve a separation width with desired forces F1 and F2. In other words, depending on the particular fabrication, different variables in Formula (1) may be fixed, while others may be changed to provide a combination of settings that will achieve a sufficient chip removal from the carrier.

After completing step S304, the method may proceed to step S306 where the portion of the carrier 114 adhered to the central portion 160 of the chip 124 separates from the chip 124 by continuing to apply a force to the chip 124 in the direction away from the carrier chuck 130 and away from the carrier 114. That is after the separation width “a” has been achieved, the transfer head 148 may continue to move in a direction away from the chuck 130 and the carrier 114 to completely peel off the remainder of the portion of the chip 124 adhered to the carrier 114. The amount of force needed to remove the remainder of the adhered portion of the chip will generally be less than the force F2 and may continuously decrease as more of the remining adhered portion of the chip gets smaller. That is, as the chip continues to separate from the adhesive, less force in the direction away from the carrier is needed. Eventually, the chip 124 is completely removed from the carrier 114.

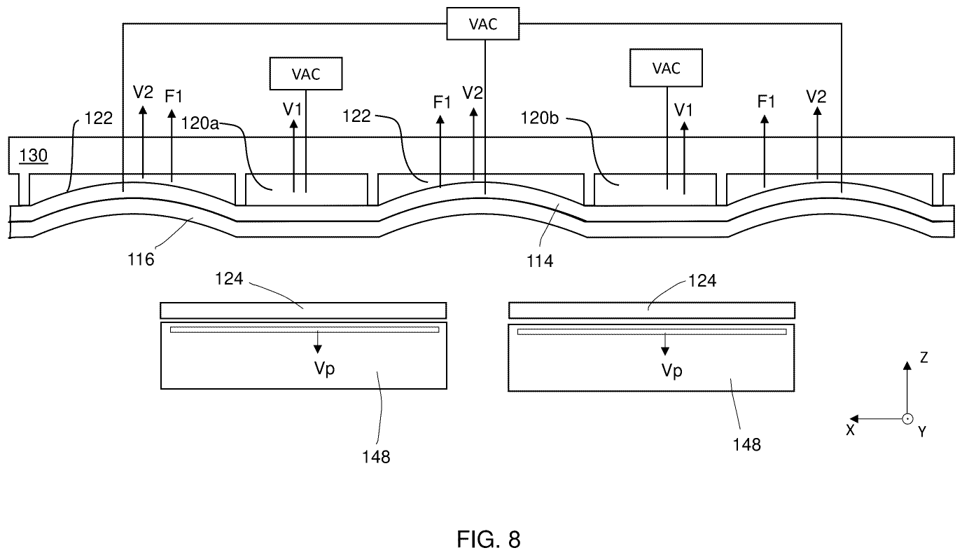

FIG. 8 shows the moment after completion of the method 300. As shown in FIG. 8, the chips 124 have been completely separated from the adhesive 116 of the carrier 114. That is, the chips 124 have been separated from carrier 114 and are now being entirely carried by the transfer heads 148. Having freed the chips 124 from the carrier, the transfer heads 148 may maintain the holding force (using for example vacuum force Vp) while the transfer heads 148 carrying the chips 124 are moved via the carriage 142 to a position underneath the bonding heads 134. Either the transfer heads 148 or the bonding heads 134 moves toward the other (or both move simultaneously) until the chips are at a position to be transferred to the bonding heads 134. Once close enough, the holding force on the transfer heads 148 may be terminated and a holding force of the bonding heads 134 may be activated, thereby transferring the chips to the plurality of bonding heads 134. After the chips 124 have been transferred to the bonding heads, the carriage 142 may be moved to position the product substrate 138 so that the bonding surface 140 arrives at a predetermined location relative to the bonding heads 134 holding the chips. That is, the processor 154 may receive/process information regarding where the chips 124 of the current bonding procedure (first set of chips) should be placed on the bonding surface 140 and based on this information, the processor will cause the carriage 142 to move such that the chips 124 held by the bonding heads 134 are properly located in the X/Y dimensions.

After the process of bonding chips to bonding surface is complete (which may include many cycles of the separating method 300 followed by the bonding step, to bond hundreds, thousands, or tens of thousands of chips), the product substrate 138 is removed from the chip bonding section 106 by for example the transfer robot 126 or the like. The product substrate may then be subjected to an annealing process (which may include one or both of heat and pressure) in which the hybrid bonding process is completed. The product substrate may be subjected to additional processes in which additional chips are added to the product substrate before or after the annealing process. The product substrate may then be subjected to additional processes, such as: singulation, testing, encapsulation, etc., which are used to produce a plurality of articles from the product substrate.

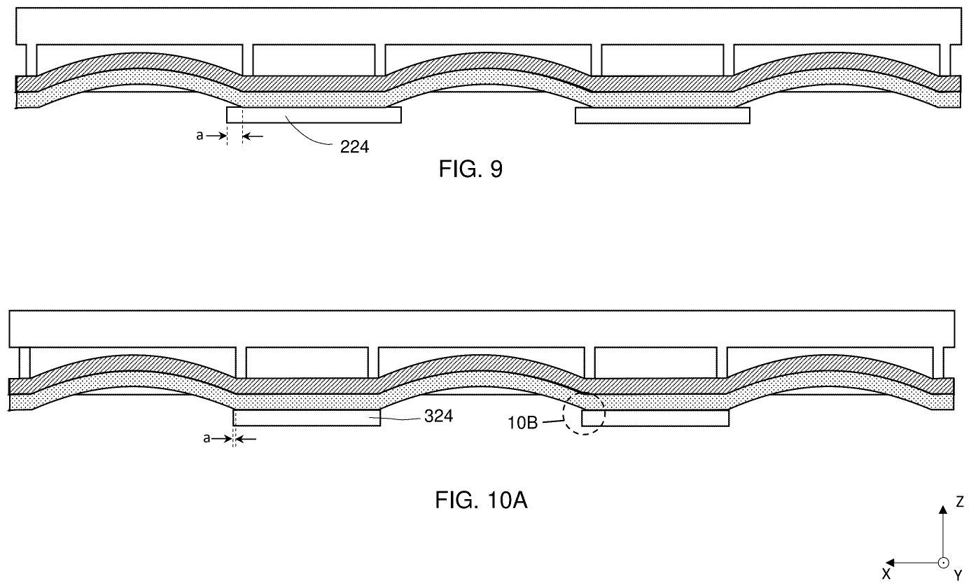

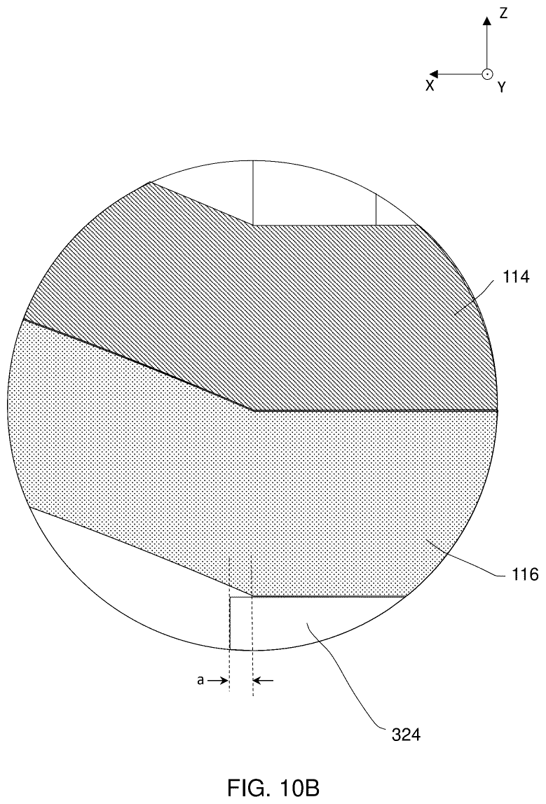

FIG. 9 shows another example embodiment in which step S304 has been performed for a different chip size. FIG. 10A shows yet another embodiment in which step S304 has been formed for yet another chip size. FIG. 10B shows an enlarged portion of FIG. 10A. In the example of FIG. 9, the chip 224 is smaller in width than the chip 124 in the example embodiment of FIGS. 7A and 7B. Accordingly, the separation width “a” in the embodiment of FIG. 9 is smaller than the separation width in the embodiment of FIGS. 7A and 7B. Similarly, in FIGS. 10A and 10B, the chip 334 has a width “a” that is smaller than both the embodiment of FIGS. 7A and 7B and the embodiment in FIG. 9. Accordingly, the separation width “a” in the embodiment of FIGS. 10A and 10B is smaller than the separation width in the embodiment of FIG. 10. That is, as noted above, the method 300 may be used for a variety of chip sizes by using Formula (1).

The above-described method enables easier peeling, reducing the distortion requirement on the chip side, thus it protects the chip from damage while allowing the chip and the carrier to be peeled away from each other.

Note that not all of the activities described above in the general description or the examples are required, that a portion of a specific activity may not be required and that one or more further activities can be performed in addition to those described. Still further, the order in which activities are listed is not necessarily the order in which they are performed. While the above description, was described in the context of hybrid bonding process, other bonding processes may be used such as soldering, flip-chip bonding, ball grid array bonding, or another process that used to form a plurality of electrical connections between chips.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A method of separating a chip from a carrier, comprising:
holding the carrier with a chuck such that a first region of the chuck overlaps a central portion of the chip and a second region of the chuck overlaps an outer portion of the chip,
applying a first vacuum pressure to the first region and applying a second vacuum pressure to the second region such that a portion of the carrier adhered to the outer portion of the chip separates from the chip while a portion of the carrier adhered to the central portion of the chip remains adhered to the chip; and
separating the portion of the carrier adhered to the central portion of the chip from the chip by applying a force to the chip in a direction away from the chuck.

2. The method of claim 1, wherein the first vacuum pressure is smaller than the second vacuum pressure.

3. The method of claim 1, wherein the first vacuum pressure is 2 to 20 kPa and the second vacuum pressure is 60 to 80 kPa.

4. The method of claim 1, wherein prior to the chuck holding the carrier, the chip is adhered to the carrier via an adhesive.

5. The method of claim 1, wherein the carrier has a Young's modulus of 1 GPa to 200 GPa.

6. The method of claim 1, wherein the chip has a Young's modulus of 50 GPa to 188 GPa.

7. The method of claim 1, wherein the carrier is made of a material selected from the group consisting of glass, silicon, quartz, and gallium arsenide.

8. The method of claim 1,
wherein the holding of the carrier with the chuck comprises applying a third vacuum pressure to the first region and the second region, and
wherein the third vacuum pressure is less than second vacuum pressure.

9. The method of claim 1, wherein the applying of the force to the chip comprises:
engaging the chip with a chip pickup member; and
moving the chip pickup member in a direction away from the carrier.

10. The method of claim 9, wherein the chip pickup member has a holding region that is larger than the first region of the chuck.

11. The method of claim 10, wherein engaging comprises engaging the holding region of the chip pickup member along a perimeter of the chip.

12. The method of claim 1, wherein the central portion is 25-95% of a surface area of the chip.

13. The method of claim 12, wherein the outer portion extends from the central portion to an edge of the chip.

14. The method of claim 1, wherein the separating of the outer portion of the chip from the chip includes applying an additional force to the chip in a direction away from the chuck.

15. The method of claim 1, wherein a width of first region is smaller than a width of the chip.

16. The method of claim 1, wherein the second region extends outside of the first region and extends beyond a width of the chip.

17. The method of claim 1, wherein the chuck comprises a land separating the first region from the second region.

18. The method of claim 1, further comprising:
holding the carrier with the chuck such that a third region of the chuck overlaps a central portion of a second chip and a fourth region of the chuck overlaps an outer portion of the second chip,
applying the first vacuum pressure to the third region and applying the second vacuum pressure to the fourth region such that a portion of the carrier adhered to the outer portion of the second chip separates from the second chip while a portion of the carrier adhered to the central portion of the second chip remains adhered to the second chip; and
separating the portion of the carrier adhered to the central portion of the second chip from the second chip by applying a force to the second chip in a direction away from the chuck.

19. A system for separating a chip from a carrier, comprising:
a chuck having a first region and a second region;
a vacuum supply;
a die pickup member;
one or more processors; and
one or more memories storing instructions, when executed by the one or more processors, causing the system to:
actuate the vacuum supply to hold the carrier with the chuck such that the first region of the chuck overlaps a central portion of the die and the second region of the chuck overlaps an outer portion of the die,
actuate the vacuum supply to apply a first vacuum pressure to the first region and to apply a second vacuum pressure to the second region such that a portion of the carrier adhered to the outer portion of the die separates from the die while a portion of the carrier adhered to the central portion of the die remains adhered to the die; and
actuate the die pickup member to separate the portion of the carrier adhered to the central portion of the die from the die by applying a force to the die in a direction away from the chuck.

20. A method of manufacturing an article, comprising:
holding a carrier with a chuck such that a first region of the chuck overlaps a central portion of a die and a second region of the chuck overlaps an outer portion of the die,
applying a first vacuum pressure to the first region and applying a second vacuum pressure to the second region such that a portion of the carrier adhered to the outer portion of the die separates from the die while a portion of the carrier adhered to the central portion of the die remains adhered to the die;
separating the portion of the carrier adhered to the central portion of the die from the die by applying a force to the die in a direction away from the chuck;
actuating a bonding head to cause the separated die to bond to a bonding surface of a substrate; and
singulating the substrate to produce the article.
